(19) United States
(12) Patent Application Publication
(10) Pub. No.: US 2024/0069118 A1
(43) Pub. Date: Feb. 29, 2024

(54) STATE QUANTITY ESTIMATION DEVICE AND STATE QUANTITY ESTIMATION METHOD

(71) Applicant: Panasonic Intellectual Property Corporation of America, Torrance, CA (US)

(72) Inventor: Taketoshi NAKAO, Kyoto (JP)

(21) Appl. No.: 18/383,971

(22) Filed: Oct. 26, 2023

Related U.S. Application Data
(63) Continuation of application No. PCT/JP2022/016035, filed on Mar. 30, 2022.

(30) Foreign Application Priority Data
May 14, 2021 (JP) 2021-082448

(51) Int. Cl. G01R 31/392; G01R 31/382; H02J 7/00

(52) U.S. Cl. CPC G01R 31/392; G01R 31/382; H02J 7/0048; H02J 7/005

(57) ABSTRACT

A state quantity estimation device includes: a sound collector that collects, in the vicinity of a secondary battery without contact with the secondary battery, a sound emitted from the secondary battery during charge or discharge of the secondary battery; an estimator that estimates a state quantity indicating a state of the secondary battery, based on information on the sound collected by the sound collector; and an outputter that outputs the state quantity estimated by the estimator.

### CROSS REFERENCE TO RELATED APPLICATIONS

This is a continuation application of PCT International Application No. PCT/JP2022/016035 filed on Mar. 30, 2022, designating the United States of America, which is based on and claims priority of Japanese Patent Application No. 2021-082448 filed on May 14, 2021. The entire disclosures of the above-identified applications, including the specifications, drawings and claims are incorporated herein by reference in their entirety.

### FIELD

The present disclosure relates to a state quantity estimation device, for example.

### BACKGROUND

A method of fully charging or fully discharging a secondary battery to estimate an internal state of the secondary battery has been known conventionally. However, this method takes a long time because the secondary battery needs to be fully charged or discharged. Thus, there is a need to estimate the internal state of the secondary battery in a shorter time.

For example, Patent Literature (PTL) 1 discloses a technology for estimating a state quantity indicating an internal state of a secondary battery, by bringing a vibration sensor into intimate contact with the secondary battery and measuring acoustic emissions (ultrasonic waves) generated inside the secondary battery during charge or discharge of the secondary battery.

### CITATION LIST

### Patent Literature

PTL 1: Japanese Unexamined Patent Application Publication No. 2012-251919

### SUMMARY

### Technical Problem

According to the technology described in PTL 1, the state quantity of the secondary battery can be estimated in a shorter time as compared to conventional methods. However, this technology cannot be used to estimate, for example, a state quantity of a secondary battery having a structure in which single cells are contained within an enclosure, such as a battery pack, because the vibration sensor needs to be brought into intimate contact with the secondary battery.

In view of the above, the present disclosure provides, for example, a state quantity estimation device that can quickly estimate a state quantity of a secondary battery in a non-contact manner.

### Solution to Problem

A state quantity estimation device according to one aspect of the present disclosure includes: a sound collector that collects, in a vicinity of a secondary battery without contact with the secondary battery, a sound emitted from the secondary battery during charge or discharge of the secondary battery; an estimator that estimates a state quantity indicating a state of the secondary battery, based on information on the sound collected by the sound collector; and an outputter that outputs the state quantity estimated by the estimator.

### Advantageous Effects

According to the present disclosure, the state quantity estimation device that can quickly estimate a state quantity of a secondary battery in a non-contact manner can be provided, for example.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram illustrating an example of a state quantity estimation system to which a state quantity estimation device is applied, according to Embodiment 1.

FIG. 2 is a block diagram illustrating an example of a functional configuration of the state quantity estimation system in Embodiment 1.

FIG. 3 is a flowchart showing an example of operations of the state quantity estimation device according to Embodiment 1.

FIG. 4 is a flowchart showing an example of a detailed flow of step S2 in FIG. 3.

FIG. 5 is a diagram showing an example of information on sounds emitted from two secondary batteries in different states of charge.

FIG. 6 is a diagram showing another example of information on the sounds emitted from the two secondary batteries in the different states of charge.

FIG. 7 is a diagram showing an example of information on sounds emitted from two secondary batteries in different states of degradation.

FIG. 8 is a diagram showing another example of information on the sounds emitted from the two secondary batteries in the different states of degradation.

FIG. 9 is a diagram showing a first example for state quantity estimation of secondary batteries according to Operation Example 1.

FIG. 10 is a diagram showing estimated values and estimation accuracy of states of charge (SoCs) calculated in the first example.

FIG. 11 is a diagram showing a second example for the state quantity estimation of secondary batteries according to Operation Example 1.

FIG. 12 is a diagram showing estimated values and estimation accuracy of states of health (SoHs) calculated in the second example.

FIG. 13 is a flowchart showing another example of the detailed flow of step S2 in FIG. 3.

FIG. 14 is a diagram to describe an example of a structure of a machine learning model.

FIG. 15 is a diagram to describe an output layer of the machine learning model.

FIG. 16 is a diagram showing an example of a training phase of the machine learning model and an estimation phase using the trained machine learning model.

FIG. 17 is a diagram showing display examples.

FIG. 18 is a block diagram illustrating an example of a functional configuration of a state quantity estimation system in Embodiment 2.

### DESCRIPTION OF EMBODIMENTS

(Knowledge Leading to the Present Disclosure)

A method of fully charging or fully discharging a secondary battery to estimate an internal state of the secondary battery has been known conventionally. However, this method takes a long time because the secondary battery needs to be fully charged or discharged. Thus, there is a need to estimate the internal state of the secondary battery in a shorter time. For example, PTL 1 discloses the technology for estimating a state quantity indicating an internal state of a secondary battery, by bringing a vibration sensor into intimate contact with the secondary battery and measuring acoustic emissions (ultrasonic waves) generated inside the secondary battery during charge or discharge of the secondary battery. However, although the technology described in PTL 1 can estimate the state quantity of the secondary battery in a shorter time as compared to the conventional methods, this technology requires that the vibration sensor be brought into intimate contact with the secondary battery. Thus, the technology described in PTL 1 cannot be used to estimate, for example, a state quantity of a secondary battery having a structure in which single cells are contained within an enclosure, such as a battery pack.

For example, a method for estimating an internal state of a secondary battery by irradiating the secondary battery with ultrasonic waves and measuring the ultrasonic waves transmitted through the secondary battery is conceivable as a method for estimating the state quantity of the secondary battery in a non-contact manner. However, according to this method, ultrasonic waves transmitted through a secondary battery cannot be measured, for example, when the secondary battery has a large thickness in the transmission direction, e.g., a secondary battery containing a plurality of single cells within an enclosure, such as a battery pack. Thus, this method lacks versatility.

In light of the above issues and as a result of intensive studies conducted by the inventors of the present disclosure, the inventors have found that a sound emitted from a secondary battery during charge or discharge of the secondary battery can be collected in a non-contact manner with the secondary battery and in the vicinity of the secondary battery, and a state quantity of the secondary battery can be estimated based on information on the collected sound. The inventors of the present disclosure also have found that the above finding enables state quantity estimation even for a secondary battery having a configuration in which single cells are contained within an enclosure, such as a battery pack.

Thus, the present disclosure can provide a state quantity estimation device, a state quantity estimation method, and a program that can quickly estimate a state quantity of a secondary battery in a non-contact manner.

### SUMMARY OF THE PRESENT DISCLOSURE

The summary of an aspect of the present disclosure is as follows.

A state quantity estimation device according to one aspect of the present disclosure includes: a sound collector that collects, in a vicinity of a secondary battery without contact with the secondary battery, a sound emitted from the secondary battery during charge or discharge of the secondary battery; an estimator that estimates a state quantity indicating a state of the secondary battery, based on information on the sound (also referred to as “sound information”) collected by the sound collector; and an outputter that outputs the state quantity estimated by the estimator.

This eliminates a need for the state quantity estimation device to fully charge or fully discharge the secondary battery in order to measure the state quantity of the secondary battery. Thus, the state quantity estimation device can quickly estimate the state quantity of the secondary battery. Moreover, since the state quantity estimation device can estimate the state quantity based on the information on the sound collected in the vicinity of the secondary battery, the state quantity estimation device can estimate the state quantity without contact with the secondary battery. This allows the state quantity estimation device to estimate a state quantity of a secondary battery, for example, held inside an enclosure without removing the secondary battery from the enclosure. Thus, the state quantity estimation device can quickly estimate the state quantity of the secondary battery in a non-contact manner.

For example, in the state quantity estimation device according to one aspect of the present disclosure, the estimator may estimate the state quantity based on an output result obtained by inputting the information on the sound into a trained model that is a machine learning model having undergone training.

This allows the state quantity estimation device to more easily extract regularity (i.e., a feature quantity) of the information on the sound by using the trained machine learning model. Thus, the state quantity estimation device can estimate the state quantity of the secondary battery more conveniently.

For example, in the state quantity estimation device according to one aspect of the present disclosure, the machine learning model may be trained using training data, and the training data may be a data set including the information on the sound and an annotation indicating at least one of a remaining battery level or a degree of degradation of the secondary battery from which the sound has been collected.

This improves the training accuracy of the machine learning model, and the state quantity estimation device can therefore estimate the state of the secondary battery with high accuracy.

For example, in the state quantity estimation device according to one aspect of the present disclosure, the information on the sound may be information including: a frequency band of the sound; and at least one of a duration of the sound, a sound pressure of the sound, or a waveform of the sound. Moreover, the information on the sound may be in a form of time-series numerical data of the sound, a spectrogram image of the sound, or a frequency characteristic image of the sound, for example.

This allows the state quantity estimation device to more easily estimate the state quantity of the secondary battery based on the regularity (i.e., the feature quantity) of the information on the sound.

For example, in the state quantity estimation device according to one aspect of the present disclosure, the state quantity may be a value of an indicator indicating at least one of a state of charge of the secondary battery or a state of degradation of the secondary battery.

This allows the state quantity estimation device to estimate the state of the secondary battery more accurately.

For example, in the state quantity estimation device according to one aspect of the present disclosure, the state quantity may be a value of at least one of a state of charge (SoC) or a state of health (SoH).

This allows the state quantity estimation device to estimate the state quantity of the secondary battery based on the value of the at least one of the SoC or the SoH.

For example, in the state quantity estimation device according to one aspect of the present disclosure, the sound may be a sound with a frequency in an ultrasonic band.

This makes the state quantity estimation device less affected by noise as compared to a case of a sound in a frequency band that can be perceived by the human sense of hearing (i.e., an audible sound). Thus, the state quantity estimation device can estimate the state quantity of the secondary battery more accurately.

A state quantity estimation method according to one aspect of the present disclosure includes: collecting, in a vicinity of a secondary battery without contact with the secondary battery, a sound emitted from the secondary battery during charge or discharge of the secondary battery; estimating a state quantity indicating a state of the secondary battery, based on information on the sound collected in the collecting; and outputting the state quantity estimated in the estimating.

This eliminates a need, in the state quantity estimation method, to fully charge or fully discharge the secondary battery in order to measure the state quantity of the secondary battery. Thus, the state quantity of the secondary battery can be quickly estimated using the state quantity estimation method. Moreover, according to the state quantity estimation method, the state quantity can be estimated based on the information on the sound collected in a non-contact manner with the secondary battery and in the vicinity of the secondary battery. Thus, the state quantity estimation method enables state quantity estimation in a non-contact manner with the secondary battery. This allows the state quantity estimation method to be used for estimating a state quantity of a secondary battery, for example, placed inside an enclosure without removing the secondary battery from the enclosure. Thus, with the state quantity estimation method, the state quantity of the secondary battery can be quickly estimated in a non-contact manner.

A program according to one aspect of the present disclosure is a program for causing a computer to execute the state quantity estimation method described above.

Thus, the same effects as the state quantity estimation method described above can be achieved by using the computer.

These general or specific aspects may be implemented using a system, a method, a device, an integrated circuit, a computer program, or a computer-readable recording medium such as a CD-ROM, or any combination of systems, methods, devices, integrated circuits, computer programs, and recording media.

Hereinafter, embodiments of the present disclosure are specifically described with reference to the accompanying Drawings. The numerical values, shapes, materials, elements, the arrangement and connection of the elements, steps, the processing order of the steps, etc. shown in the following exemplary embodiments are mere examples, and therefore do not limit the scope of the appended Claims and their equivalents. Moreover, among the elements in the following exemplary embodiments, those not recited in any one of the independent claims, representing the most superordinate concept, are described as optional elements. Furthermore, each of the Drawings is not necessarily an illustration drawn in a strict sense. In each of the Drawings, substantially identical elements are denoted by the same reference numerals, and duplicated descriptions may be omitted or simplified.

In the present disclosure, terms describing relationships between elements, such as “parallel” and “perpendicular,” and terms indicating shapes of elements, such as “rectangular,” as well as numerical values are not intended to express strict meaning only, but rather intended to encompass substantially equivalent ranges, e.g., differences of about a few percent.

### Embodiment 1

Embodiment 1 will now be specifically described with reference to the drawings.

[State Quantity Estimation System]

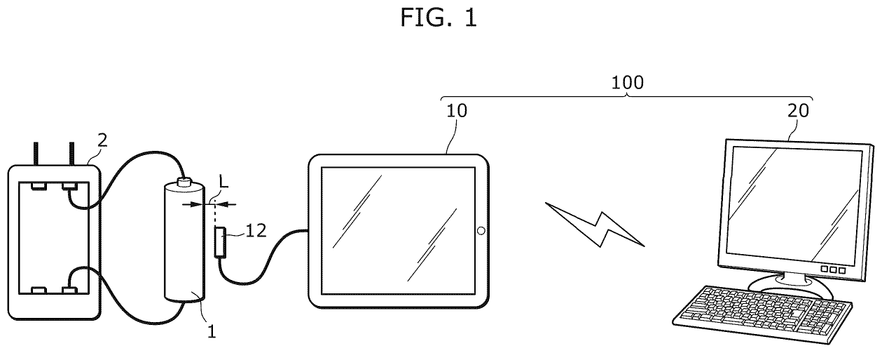

First, a state quantity estimation system will be described with reference to FIG. 1. FIG. 1 is a diagram illustrating an example of state quantity estimation system 100 to which state quantity estimation device 10 is applied, according to Embodiment 1.

State quantity estimation system 100 collects, in the vicinity of secondary battery 1 without contact with secondary battery 1, a sound emitted from secondary battery 1 during charge or discharge of secondary battery 1. State quantity estimation system 100 then estimates a state quantity indicating a state of secondary battery 1, based on information on the collected sound and outputs the estimated state quantity to terminal device 20.

FIG. 1 shows an example in which sound collector 12 of state quantity estimation device 10 is disposed in the vicinity of secondary battery 1 (e.g., within a range of distance L in FIG. 1) to collect a sound emitted from secondary battery 1 while secondary battery 1 is set in charger 2 and being charged. At this time, sound collector 12 is disposed at a position not in contact with, but in proximity to, secondary battery 1. For example, sound collector 12 is spaced apart from secondary battery 1 by distance L. Distance L may be, for example, a distance within a range greater than 0 mm and less than or equal to 50 mm from a surface of secondary battery 1. Distance L may be a distance on the order of cm, on the order of mm, or on the order of μm.

[1. Configuration]

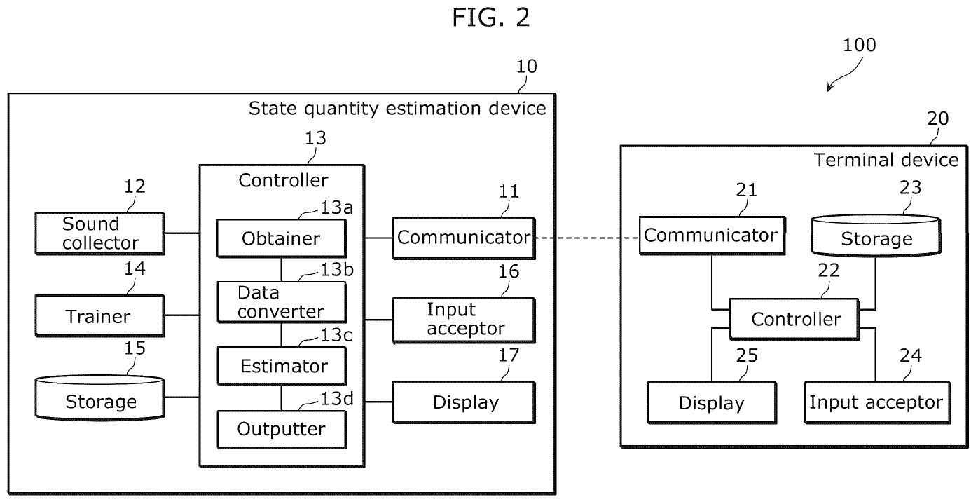

A configuration of state quantity estimation system 100 will be described next. FIG. 2 is a block diagram illustrating an example of a functional configuration of state quantity estimation system 100 in Embodiment 1.

As shown in FIGS. 1 and 2, state quantity estimation system 100 includes, for example, state quantity estimation device 10 and terminal device 20. Configurations of these components will be described below.

[State Quantity Estimation Device]

State quantity estimation device 10 collects, in the vicinity of secondary battery 1 without contact with secondary battery 1, a sound emitted from secondary battery 1 during charge or discharge of secondary battery 1. State quantity estimation device 10 then estimates a state quantity indicating a state of secondary battery 1, based on information on the collected sound and outputs the estimated state quantity. The outputted state quantity may be displayed on display 17 of state quantity estimation device 10 or on display 25 of terminal device 20. This allows a user of state quantity estimation device 10 to check the state quantity of secondary battery 1.

State quantity estimation device 10 includes, for example, communicator 11, sound collector 12, controller 13, trainer 14, storage 15, input acceptor 16, and display 17.

Communicator 11 is a communication module (communication circuit) used by state quantity estimation device 10 to communicate with terminal device 20. Communicator 11 may be, for example, a wireless communication circuit that performs wireless communication or a wired communication circuit that performs wired communication. The standard of such communication performed by communicator 11 is not limited to any particular communications standard. For example, when state quantity estimation device 10 and terminal device 20 communicate with each other via a local communication network, communicator 11 may function as a local communication circuit. When state quantity estimation device 10 and terminal device 20 communicate with each other via a wide-area communication network, communicator 11 may function as a wide-area communication circuit.

Sound collector 12 collects, in the vicinity of secondary battery 1, a sound emitted from secondary battery 1 during charge or discharge of secondary battery 1. More specifically, sound collector 12 collects the sound at a position not in contact with, but in proximity to, secondary battery 1. As described above, sound collector 12 collects the sound emitted from secondary battery 1 at the position spaced apart from secondary battery 1 by distance L. Distance L has been described above, and therefore the description of distance L is omitted here. In the example shown in FIG. 1, sound collector 12 is connected to a main body (more specifically, controller 13) of state quantity estimation device 10 via wired communication. However, sound collector 12 may be connected to the main body of state quantity estimation device 10 via wireless communication. In this case, the sound collected by sound collector 12 is obtained by obtainer 13a of controller 13 via communicator 11. Sound collector 12 converts the collected sound into an electrical signal and then outputs the converted electrical signal. Sound collector 12 is, for example, a microphone or a microphone device.

Controller 13 performs information processing to control operations of state quantity estimation device 10. Controller 13 is implemented by a microcomputer, for example, but may also be implemented by a processor or a dedicated circuit. Specifically, controller 13 includes obtainer 13a, data converter 13b, estimator 13c, and outputter 13d. Each of obtainer 13a, data converter 13b, estimator 13c, and outputter 13d is implemented by a processor executing a program to perform the information processing described above.

Obtainer 13a obtains the electrical signal of the sound (e.g., a digital signal of the sound) outputted by sound collector 12.

Data converter 13b converts the electrical signal of the sound obtained by obtainer 13a into a predetermined form of information. This generates sound information. The sound information is, for example, information including: a frequency band of the sound; and at least one of a duration, a sound pressure, or a waveform of the sound. The sound information may further include a time at which the sound was collected. The sound information may be, for example, in the form of time-series numerical data of the sound, a spectrogram image of the sound, or a frequency characteristic image of the sound. If sound information is in the form of an image, the sound information may be image data in a format such as Joint Photographic Experts Group (JPEG) or Basic Multilingual Plane (BMP), for example. If sound information is in the form of time-series numerical data, the sound information may be numerical data in a format such as Waveform Audio File Format (WAV). For example, data converter 13b converts, through a fast Fourier transform (FFT) analysis, frequency components included in the electrical signal of the sound obtained by obtainer 13a into a frequency spectrum or spectrogram of the sound and generates time-series numerical data (e.g., time-series numerical data of the frequency characteristic or spectrogram) of the sound, a spectrogram image of the sound, or a frequency characteristic image of the sound.

Estimator 13c estimates the state quantity indicating the state of secondary battery 1, based on the sound information generated by data converter 13b. The sound information used to estimate the state quantity may be, for example, information on a sound having a frequency in an ultrasonic band. This makes estimator 13c less affected by a sound that is noise as compared to a case of a sound in a frequency band that can be perceived by the human sense of hearing (i.e., an audible sound), for example. Thus, the state quantity of secondary battery 1 can be estimated more accurately.

The state quantity of secondary battery 1 is a value of an indicator that indicates at least one of a state of charge or a state of degradation (also referred to as a state of health) of secondary battery 1. For example, the state quantity is a value of at least one of a state of charge (SoC) or a state of health (SoH). In this specification, a state of charge of secondary battery 1 is also referred to as a remaining level of secondary battery 1, a remaining battery level, a charge level, or an SoC. A state of degradation of secondary battery 1 is also referred to as a degree of degradation, a degree of health, a state of health, or an SoH.

For example, estimator 13c may derive an estimated value of the state quantity of secondary battery 1 based on the sound information using one or more predetermined arithmetic expressions. Alternatively, estimator 13c may use a machine learning model having undergone training (hereinafter, referred to as a trained model), which is stored in storage 15, to derive an estimated value of the state quantity of secondary battery 1 based on output results obtained by inputting the sound information into the trained model, for example. These specific estimation processes will be described later in operation examples.

Outputter 13d outputs the state quantity of secondary battery 1, which is estimated by estimator 13c (in other words, the estimated value of the state quantity of secondary battery 1, which is derived by estimator 13c). The state quantity outputted by outputter 13d may be displayed on display 17 or outputted to terminal device 20 via communicator 11, for example.

Trainer 14 performs machine learning using training data. Trainer 14 generates, through machine learning, a machine learning model (i.e., a trained model) that takes sound information as an input and outputs at least one of a remaining battery level (e.g., an SoC value) or a degree of degradation (e.g., an SoH value) of secondary battery 1 from which the sound has been collected. The training data used for training the machine learning model is a data set including information on a sound emitted by secondary battery 1 during charge or discharge, and an annotation indicating at least one of a remaining battery level or a degree of degradation of secondary battery 1 from which the sound has been collected.

The machine learning model is, for example, a neural network model, more specifically, a convolutional neural network (CNN) or recurrent neural network (RNN) model. If the machine learning model is a CNN, for example, the trained machine learning model (i.e., the trained model) outputs a state quantity of secondary battery 1, which has been estimated as a result of a spectrogram image or a frequency characteristic image being inputted into the trained machine learning model. Alternatively, if the machine learning model is an RNN, for example, the trained model outputs a state quantity of secondary battery 1, which has been estimated as a result of time-series numerical data of a frequency characteristic or spectrogram being inputted into the trained model. The trained model includes trained parameters adjusted by machine learning. The generated trained model is stored in storage 15. Trainer 14 is implemented, for example, by a processor executing a program stored in storage 15.

Storage 15 is a storage device in which control programs to be executed by controller 13, for example, are stored. Storage 15 may temporarily store training data, and sound information used for estimation. Storage 15 updates the stored trained models with the machine learning model (i.e., the trained model) generated by trainer 14. Storage 15 is implemented, for example, by a semiconductor memory.

Input acceptor 16 accepts an operational input from the user. Specifically, input acceptor 16 is implemented by a mouse, a microphone, or a touch panel, for example. Note that input acceptor 16 obtains a voice and outputs a voice signal in accordance with the obtained voice. Specific examples of the microphone include condenser microphones, dynamic microphones, or micro electro mechanical systems (MEMS) microphones. A speaker outputs a voice (synthesized voice) in response to a speech sound obtained by the microphone, for example. This allows the user to input a control execution instruction in an interactive manner.

Note that input acceptor 16 may be equipped with a camera (not shown). The camera captures an image of the user operating state quantity estimation device 10. Specifically, the camera captures movements of the user's mouth, eyes, or fingers. In this case, input acceptor 16 accepts an operation from the user based on the image of the user captured by the camera. The camera is implemented, for example, by a complementary metal oxide semiconductor (CMOS) image sensor.

Display 17 is a display device that displays presentation information to be shown to the user based on control performed by controller 13. The presentation information may be, for example, image data or text data containing the state quantity of secondary battery 1 estimated by state quantity estimation device 10. Display 17 is implemented by a liquid crystal panel or an organic electro-luminescence (EL) panel.

[Terminal Device]

Terminal device 20 is, for example, a smartphone, a tablet terminal, or a personal computer. Terminal device 20 includes display 25 that obtains the state quantity outputted from state quantity estimation device 10 and displays, and thus presents to the user, presentation information including the obtained state quantity. Terminal device 20 may, for example, derive predetermined information based on the state quantity according to an instruction inputted by the user and present the derived information to the user. For example, if the user inputs an instruction to derive a usable time of the device being used by the user based on the state quantity of secondary battery 1, terminal device 20 may derive the usable time of the device as the predetermined information described above, and may present, to the user, presentation information including the state quantity of secondary battery 1 and the usable time of the device. Terminal device 20 includes communicator 21, controller 22, storage 23, input acceptor 24, and display 25, for example.

Communicator 21 is a communication module (communication circuit) used by terminal device 20 to communicate with state quantity estimation device 10. Communicator 21 may be, for example, a wireless communication circuit that performs wireless communication or a wired communication circuit that performs wired communication. The standard of such communication performed by communicator 21 is not limited to any particular communications standard.

Controller 22 performs information processing to control operations of terminal device 20. For example, controller 22 causes communicator 21 to transmit a control signal in accordance with a user input accepted by input acceptor 24. Controller 22 is implemented by a microcomputer, for example, but may also be implemented by a processor or a dedicated circuit.

Storage 23 is a storage device in which control programs to be executed by controller 22, for example, are stored. Storage 23 is implemented, for example, by a semiconductor memory.

Input acceptor 24 accepts an operational input from the user. Input acceptor 24 is implemented, for example, by a touch panel as with input acceptor 16 of state quantity estimation device 10.

Display 25 displays presentation information to be shown to the user based on control performed by controller 22. Display 25 is implemented, for example, by a liquid crystal panel or an organic EL panel.

[2. Operations]

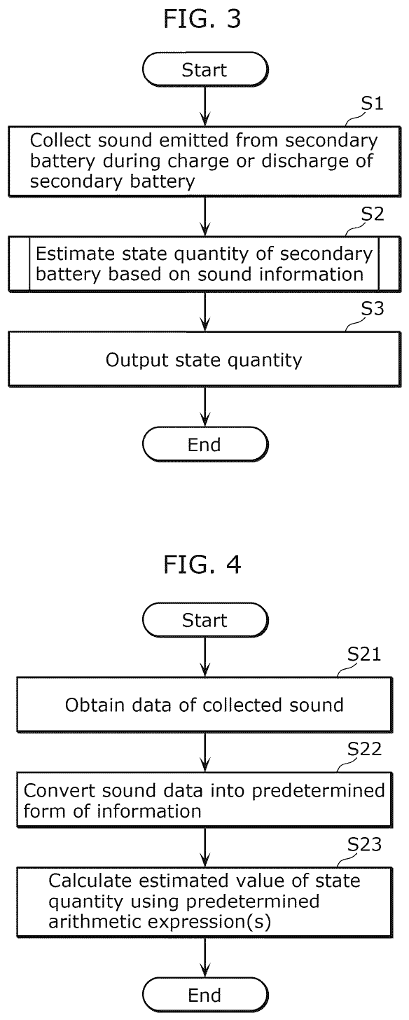

Operations of state quantity estimation device 10 according to Embodiment 1 will be described next. FIG. 3 is a flowchart showing an example of the operations of the state quantity estimation device according to Embodiment 1.

First, sound collector 12 of state quantity estimation device 10 collects a sound emitted from secondary battery 1 during charge or discharge of secondary battery 1 (S1). As shown in FIG. 1, sound collector 12 collects the sound in the vicinity of secondary battery 1. Sound collector 12 collects the sound in proximity to secondary battery 1 without contact with secondary battery 1.

Next, estimator 13c of state quantity estimation device 10 estimates a state quantity indicating a state of secondary battery 1, based on information on the sound collected in step S1 (S2). Details of the flow of step S2 will be described below in Operation Example 1 and Operation Example 2.

Next, outputter 13d of state quantity estimation device 10 outputs the state quantity estimated in step S2 (S3). As mentioned above, outputter 13d may output the state quantity to display 17 of state quantity estimation device 10 or to terminal device 20 in accordance with an instruction inputted by the user.

### Operation Example 1

Operation Example 1 of state quantity estimation device 10 in step S2 of FIG. 3 will be described next. Operation Example 1 describes a flow of estimating a state quantity, in which estimator 13c of state quantity estimation device 10 calculates an estimated value of the state quantity of secondary battery 1 using one or more predetermined arithmetic expressions. FIG. 4 is a flowchart showing an example of the detailed flow of step S2 in FIG. 3.

In Operation Example 1 of step S2, obtainer 13a of state quantity estimation device 10 first obtains data of the sound collected by sound collector 12 in step S1 (S21). The sound data is an electrical signal of the sound, which is converted by sound collector 12.

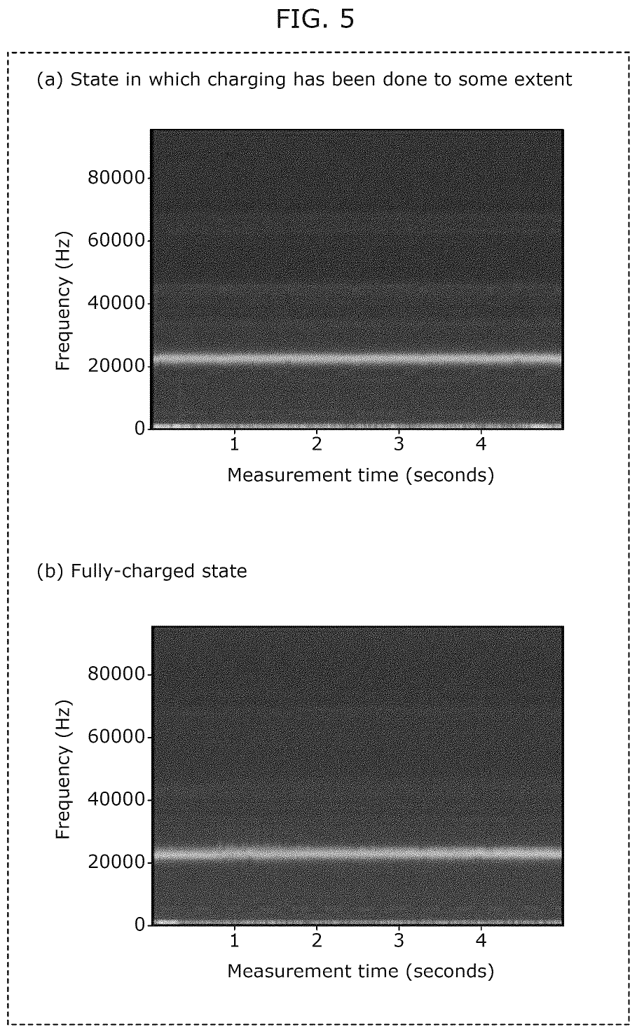

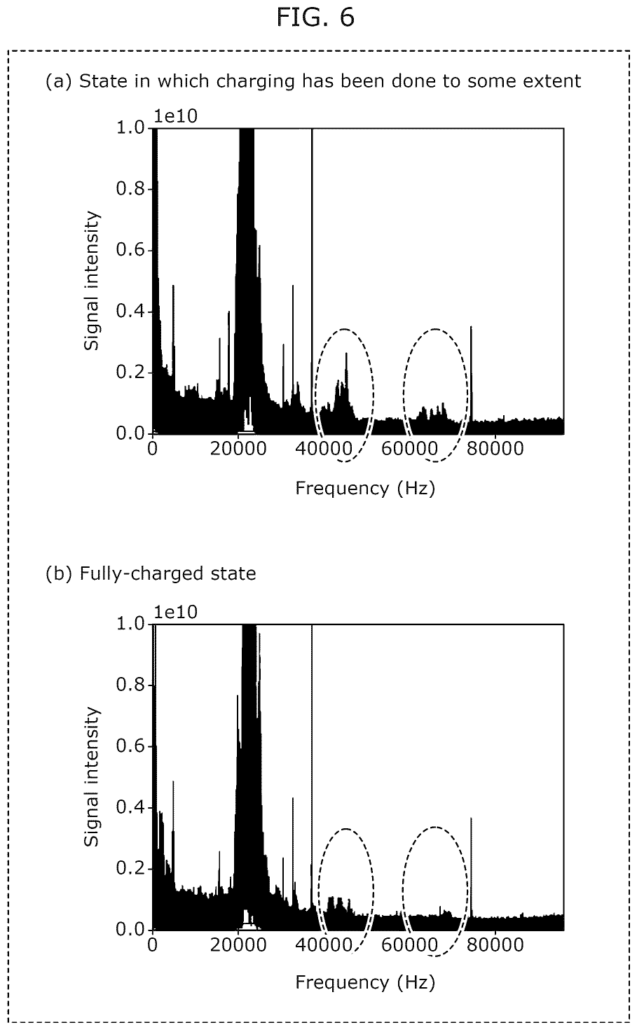

Next, data converter 13b of state quantity estimation device converts the sound data (i.e., the electrical signal) obtained by obtainer 13a in step S21 into a predetermined form of information (S22). This generates sound information. FIG. 5 is a diagram showing an example of information on sounds emitted from two secondary batteries in different states of charge. FIG. 6 is a diagram showing another example of information on the sounds emitted from the two secondary batteries in the different states of charge. Each item of sound information shown in FIG. 5 is a spectrogram image, and each item of sound information shown in FIG. 6 is a frequency characteristic image.

Each of the spectrogram images shown in FIG. 5 is an image showing, in a grayscale representation, time variation of signal intensity in the frequency characteristic, with a horizontal axis representing time (seconds) and a vertical axis representing frequencies (Hz). Here, higher whiteness indicates stronger signal intensity in the frequency characteristic. In FIG. 5, (a) shows a spectrogram image of a sound emitted from secondary battery 1 in a state in which charging has been done to some extent, and (b) shows a spectrogram image of a sound emitted from secondary battery 1 in a fully-charged state.

Each of the frequency characteristics shown in FIG. 6 is obtained by performing Fourier transform on time-series numerical data of the sound collected by sound collector 12. In FIG. 6, (a) and (b) show frequency characteristic images corresponding to (a) and (b) of FIG. 5, respectively.

Next, estimator 13c of state quantity estimation device 10 calculates an estimated value of a state quantity of secondary battery 1 using one or more predetermined arithmetic expressions (S23). Specifically, estimator 13c calculates the estimated value of the state quantity of secondary battery 1, for example, using values obtained by substituting signal intensities of spectra in specific frequency bands, which are obtained from the sound information generated in step S22, into predetermined arithmetic expressions. The calculated estimated value of the state quantity of secondary battery 1 is an estimated value of at least one of an SoC, which indicates a state of charge of secondary battery 1, or an SoH, which indicates a state of degradation of secondary battery 1. With respect to a state quantity indicating a state of charge of secondary battery 1 (i.e., SoC), for example, a predetermined relationship can be derived from information on sounds emitted from secondary batteries in different states of charge. Therefore, based on this relationship, the estimated value of the state quantity may be calculated using the predetermined arithmetic expressions. As shown in FIGS. 5 and 6, for example, at the time of charging, signal intensities around 45 kHz and 65 kHz in the information on the sound emitted from the secondary battery in the state in which charging has been done to some extent (shown in (a)) are higher than signal intensities around 45 kHz and 65 kHz in the information on the sound emitted from the secondary battery in the fully-charged state (shown in (b)). In other words, the better the state of charge of the secondary battery, the lower the sound pressures around 45 kHz and 65 kHz in the sound emitted from the secondary battery. Therefore, based on this relationship, an estimated value of an SoC indicating a state of charge of secondary battery 1 may be calculated using arithmetic expressions to be described below.

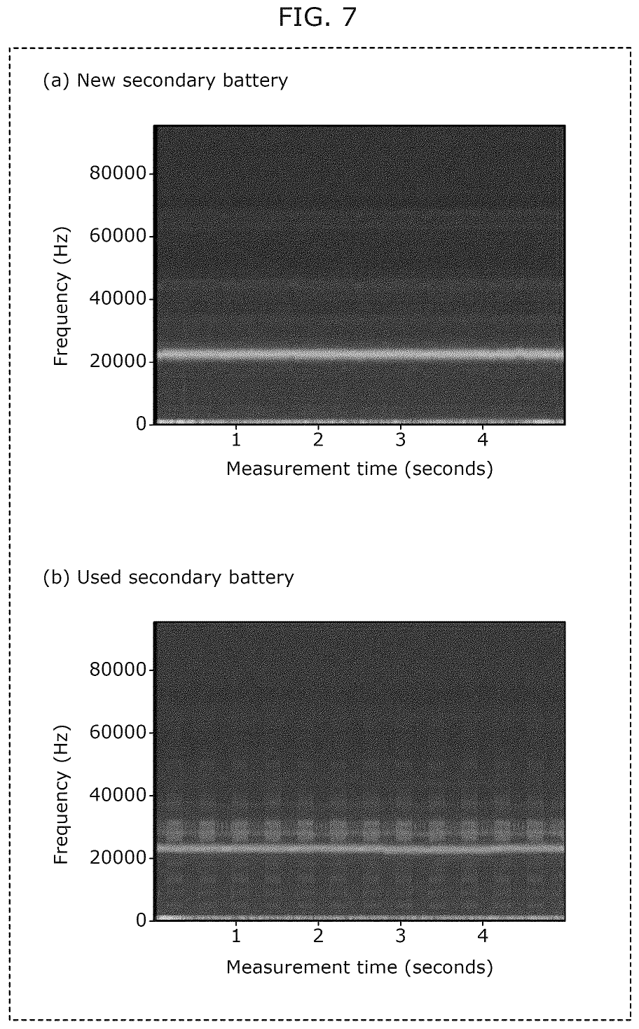

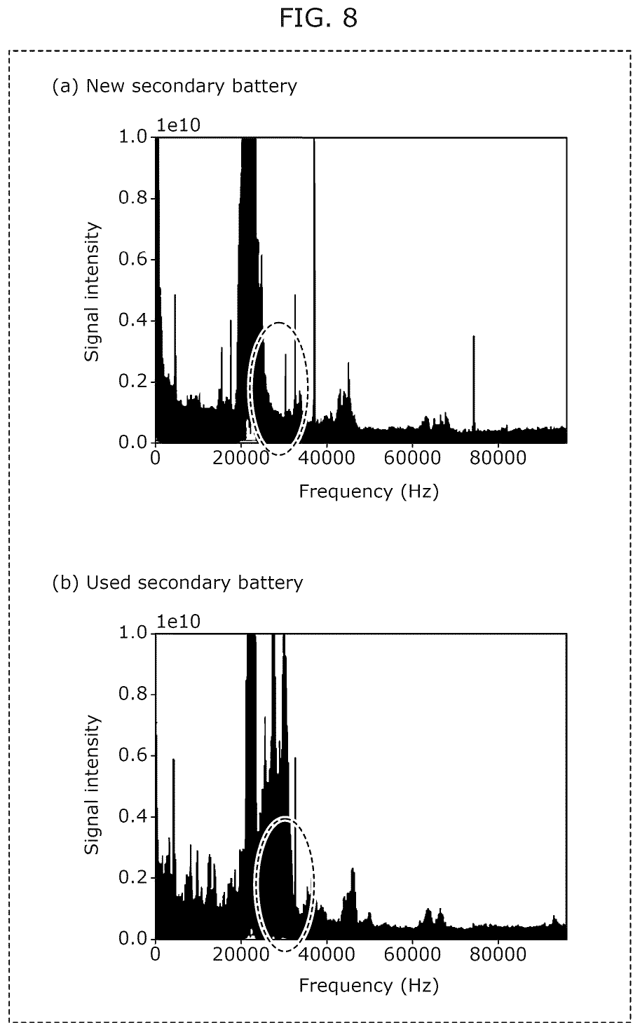

With respect to a state quantity indicating a state of degradation (i.e., a state of health) of secondary battery 1 (i.e., SoH), for example, a predetermined relationship can be derived from information on sounds emitted from secondary batteries in different states of degradation. FIG. 7 is a diagram showing an example of information on sounds emitted from two secondary batteries in different states of degradation. FIG. 8 is a diagram showing another example of information on the sounds emitted from the two secondary batteries in the different states of degradation. As shown in FIGS. 7 and 8, for example, at the time of charging, a signal intensity around 23 kHz is strong in the information on the sound emitted from the new secondary battery in a state in which charging has been done to some extent (shown in (a)), but a peak around 23 kHz is split and shifted to around 25 kHz to 30 kHz in the information on the sound emitted from the well-used (also referred to as “used”) secondary battery in a state in which charging has been done to some extent (shown in (b)). In other words, as the secondary battery becomes more degraded (i.e., as the state of health becomes more degraded), the sound pressure around 23 kHz decreases and the sound pressure around 25 kHz to 30 kHz increases in the sound emitted from the secondary battery. Therefore, based on this relationship, an estimated value of an SoH, which indicates a state of degradation of secondary battery 1, may be calculated using an arithmetic expression to be described below.

### Specific Examples of State Quantity Estimation According to Operation Example 1

The state quantity estimation according to Operation Example 1 will be described next with reference to a first example and a second example. A size AA rechargeable nickel-hydrogen battery (BK-3MCC) manufactured by Panasonic Corporation was used as a secondary battery, and BQ-CC23 manufactured by Panasonic Corporation was used as a charger.

### First Example

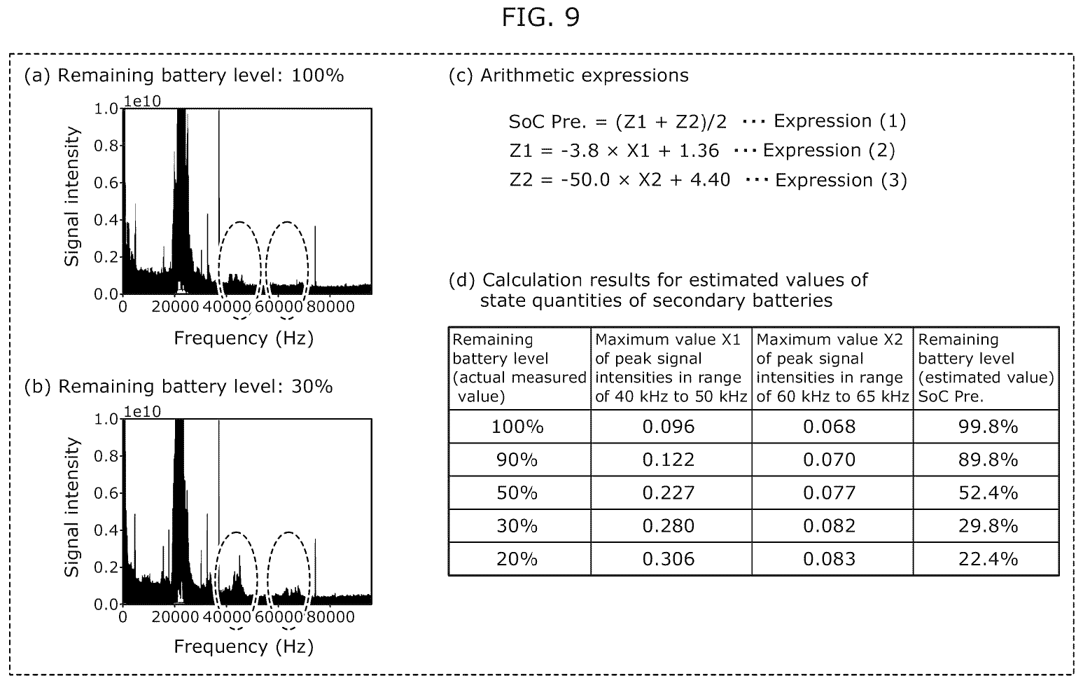

FIG. 9 is a diagram showing the first example for the state quantity estimation of secondary batteries according to Operation Example 1. The first example describes an example in which an estimated value of a state quantity (in this case, SoC) indicating a state of charge of a secondary battery is calculated, using the predetermined arithmetic expressions, based on information on a sound emitted from the secondary battery during charge of the secondary battery.

In FIG. 9, (a) shows information (here, a frequency characteristic image) on a sound emitted from the secondary battery when the remaining battery level of the secondary battery is 100%, and (b) shows information on a sound emitted from the secondary battery when the remaining battery level of the secondary battery is 30%. In FIG. 9, (c) shows the arithmetic expressions for calculating an estimated value of a state quantity (SoC), which indicates a state of charge of the secondary battery, and (d) shows calculation results for estimated values (SoC Pre.) of state quantities. Here, peaks with intensities above a predetermined value (e.g., 1e10) are not considered.

A maximum value X1 of peaks in a range of 40 kHz to 50 kHz and a maximum value X2 of peaks in a range of 60 kHz to 65 kHz are derived from the sound information shown in (a) of FIG. 9. Then, the value of X1 is substituted into Expression (2) shown in (c) of FIG. 9, and the value of X2 is substituted into Expression (3). Then, Z1 and Z2 calculated by Expressions (2) and (3) are substituted into Expression (1). This calculates the estimated value of the state quantity (SoC) indicating the state of charge of the secondary battery. As shown in (d) of FIG. 9, when the remaining battery level was 100% (as an actual measured value), the estimated value (SoC Pre.) of the remaining battery level was 99.8%.

Subsequently, also for the sound information shown in (b) of FIG. 9, the estimated value of the state quantity (SoC) indicating the state of charge of the secondary battery was calculated in the same way as in (a) of FIG. 9. As shown in (d) of FIG. 9, when the remaining battery level was 30% (as an actual measured value), the estimated value (SoC Pre.) of the remaining battery level was 29.8%.

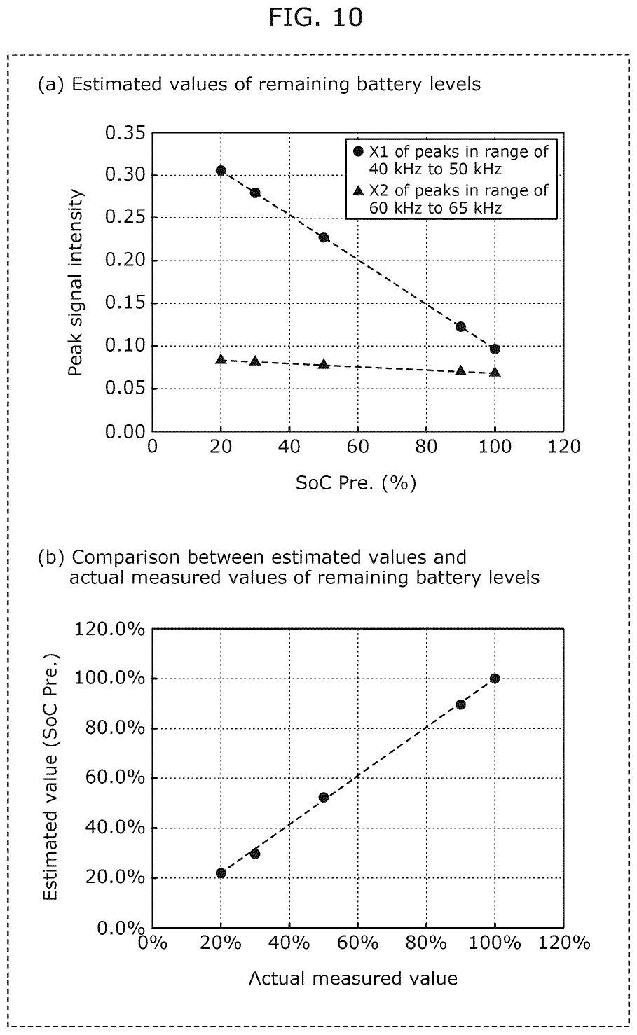

Furthermore, as shown in (d) of FIG. 9, SoC estimated values of the secondary batteries with the remaining battery levels being 20%, 50%, and 90% were calculated, and the estimated values were compared with corresponding actual measured values to confirm estimation accuracy. FIG. 10 is a diagram showing the estimated values and the estimation accuracy of SoCs calculated in the first example. In (a) of FIG. 10, a graph shows a relationship between the maximum peak intensity values X1 in the range of 40 kHz to 50 kHz and the maximum peak intensity values X2 in the range of 60 kHz to 65 kHz, and the estimated values (SoC Pre.) of the remaining battery levels, which are shown in (d) of FIG. 9. In (b) of FIG. 10, a graph shows a relationship between the estimated values (SoC Pre.) and the actual measured values of the remaining battery levels.

As shown in (a) of FIG. 10, the maximum values X1 and the maximum values X2 respectively have a linear relationship with the estimated values (SoC Pre.) of the remaining battery levels. As shown in (b) of FIG. 10, the estimated values (SoC Pre.) of the remaining battery levels of the secondary batteries are aligned on a straight line and correspond to the actual measured values.

As described above, the estimated values of the state quantities (SoCs) of the secondary batteries that are calculated, using the predetermined arithmetic expressions, based on the information on the sounds emitted from the secondary batteries during charge of the secondary batteries are substantially the same as the actual measured values. Thus, an SoC value of a secondary battery can be estimated according to Operation Example 1.

### Second Example

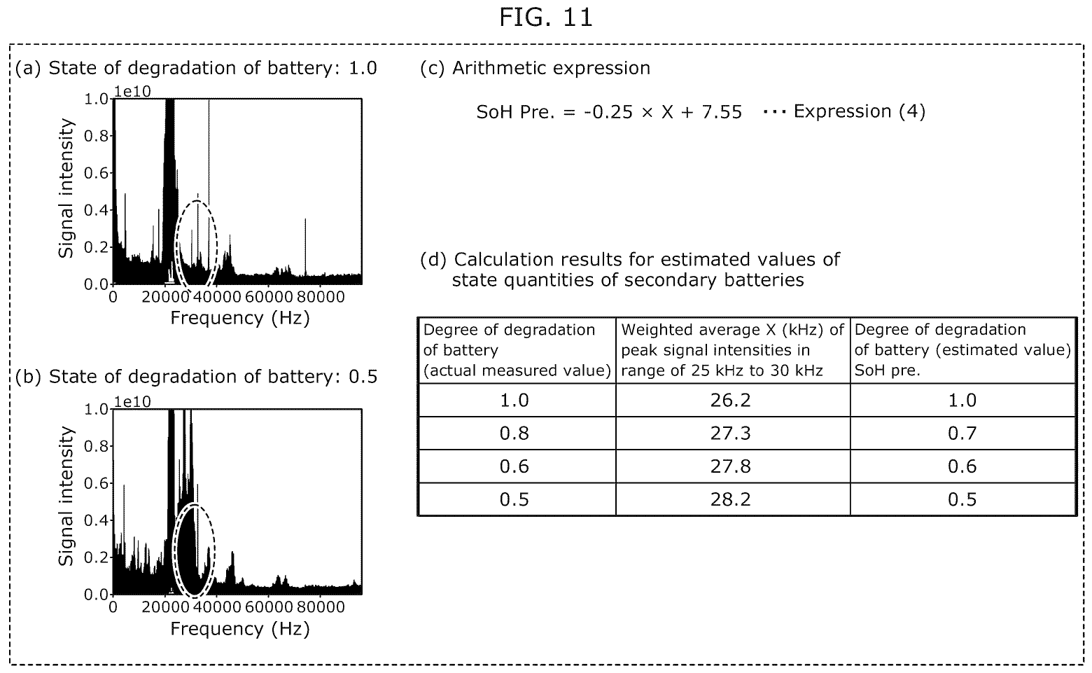

FIG. 11 is a diagram showing the second example for the state quantity estimation of secondary batteries according to Operation Example 1. The second example describes an example in which an estimated value of a state quantity (in this case, SoH) indicating a state of degradation (also referred to as a state of health) of a secondary battery is calculated, using a predetermined arithmetic expression, based on information on a sound emitted from the secondary battery during charge of the secondary battery.

In FIG. 11, (a) shows information (here, a frequency characteristic image) on a sound emitted from the secondary battery when the state of degradation (hereinafter, also referred to as the degree of degradation) of the secondary battery is 1.0, and (b) shows information on a sound emitted from the secondary battery when the state of degradation of the secondary battery is 0.5. Here, the state of degradation of the secondary battery being 1.0 refers to a state of degradation in a new secondary battery in a fully-charged state, for example. If a quantity of electricity when a new secondary battery is fully charged is defined to be 1, for example, the state of degradation of a secondary battery being 0.5 refers to a state of degradation of a secondary battery of the same type that is fully charged at half the quantity of electricity. In FIG. 11, (c) shows the arithmetic expression for calculating an estimated value (SoH Pre.) of a state quantity (SoH), which indicates a state of degradation of a secondary battery, and (d) shows calculation results for estimated values (SoH Pre.) of state quantities. Here, peaks with intensities above a predetermined value (e.g., 1e10) are not considered.

A weighted average X of peak intensities in a range of 25 kHz to 30 kHz is derived based on the sound information shown in (a) of FIG. 11. Then, the value of X is substituted into Expression (4) shown in (c) of FIG. 11. This calculates the estimated value (SoH Pre.) of the state quantity (SoH) indicating the state of degradation of the secondary battery. As shown in (d) of FIG. 11, when the degree of degradation of the secondary battery was 1.0 (as an actual measured value), the estimated value (SoH Pre.) of the degree of degradation of the secondary battery was 1.0. Note that the weighted average is an arithmetic mean of the products of peak intensities and frequencies, which are calculated for every 1 kHz in a range from 25 kHz to 30 kHz.

Subsequently, also for the sound information shown in (b) of FIG. 11, an estimated value (SoH Pre.) of the state quantity (SoH) indicating the state of degradation of the secondary battery was calculated in the same way as in (a) of FIG. 11. As shown in (d) of FIG. 11, when the degree of degradation of the secondary battery was 0.5 (as an actual measured value), the estimated value (SoH Pre.) of the degree of degradation of the secondary battery was 0.5.

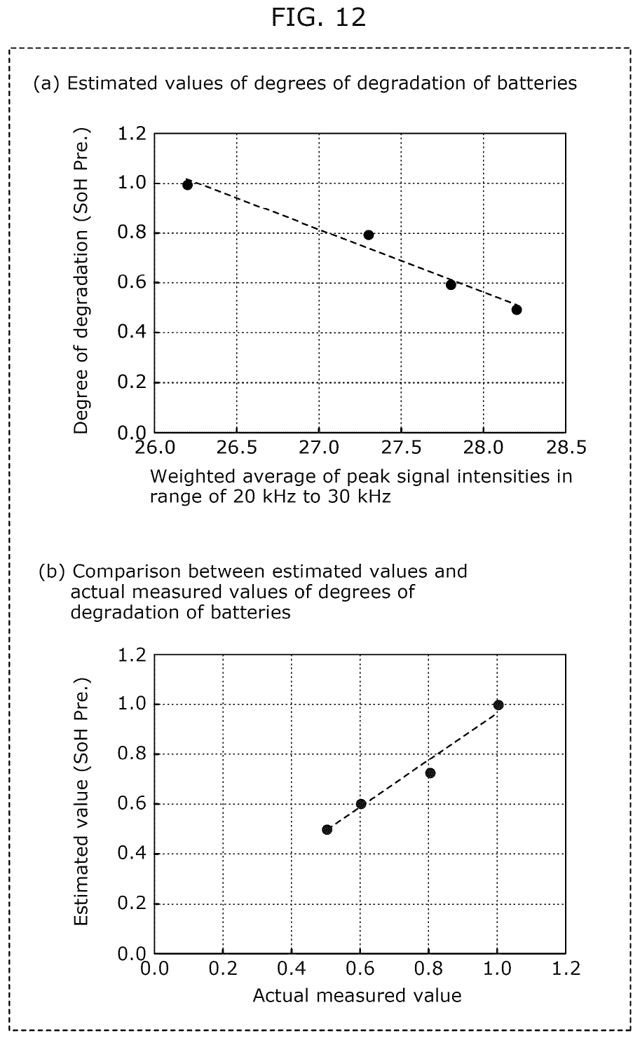

Furthermore, as shown in (d) of FIG. 11, SoH estimated values of the secondary batteries with the degrees of degradation being 0.6 and 0.8 were calculated, and the estimated values were compared with corresponding actual measured values to confirm estimation accuracy. FIG. 12 is a diagram showing the estimated values and the estimation accuracy of SoHs calculated in the second example. In (a) of FIG. 12, a graph shows a relationship between the weighted averages X of the peak intensities in the range of 25 kHz to 30 kHz and the estimated values (SoH Pre.) of the degrees of degradation of the secondary batteries, which are shown in (d) of FIG. 11. In (b) of FIG. 12, a graph shows a relationship between the estimated values (SoH Pre.) and the actual measured values for the degrees of degradation of the secondary batteries.

As shown in (a) of FIG. 12, the weighted averages X of the peak intensities in the range of 25 kHz to 30 kHz have a linear relationship with the estimated values (SoH Pre.) of the degrees of degradation of the secondary batteries. Moreover, as shown in (b) of FIG. 12, the estimated values (SoH Pre.) of the degrees of degradation of the secondary batteries are aligned on a straight line and respectively correspond to the actual measured values.

As described above, the estimated values of the state quantities (SoHs) of the secondary batteries that are calculated, using the predetermined arithmetic expression, based on the information on the sounds emitted from the secondary batteries during charge of the secondary batteries are substantially the same as the corresponding actual measured values. Thus, an SoH value of a secondary battery can be estimated according to Operation Example 1.

### Operation Example 2

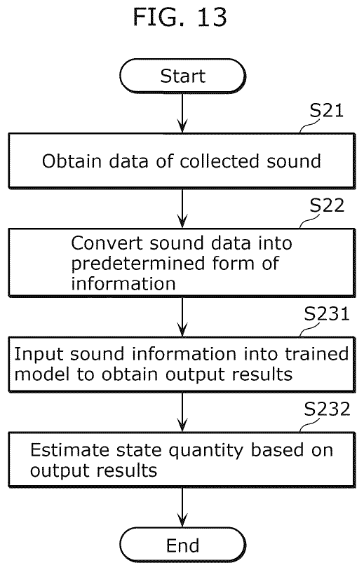

Operation Example 2 of state quantity estimation device 10 in step S2 of FIG. 3 will be described next. Operation Example 2 describes a flow in which estimator 13c of state quantity estimation device 10 estimates a state quantity of secondary battery 1 based on output results obtained by inputting sound information into a trained model. FIG. 13 is a flowchart showing another example of the detailed flow of step S2 in FIG. 3. In FIG. 13, the same step numbers are assigned to processes that are common to those in FIG. 4. Here, points different from those in Operation Example 1 will be mainly described, and duplicated descriptions will be simplified or omitted.

In Operation Example 2 of step S2, obtainer 13a of state quantity estimation device 10 obtains data of the sound collected by sound collector 12 in step S1 (S21), and then data converter 13b converts the sound data (i.e., an electrical signal) obtained by obtainer 13a in step S21 into a predetermined form of information (S22) in the same way as in Operation Example 1. This generates sound information. Since the sound information has been described in Operation Example 1 with reference to FIGS. 5 to 8, the description of the sound information is omitted here.

Next, estimator 13c of state quantity estimation device 10 inputs the sound information generated in step S22 into a trained model to obtain output results (S231). Before describing the specific process of step S231, the trained model used in this step will be described first.

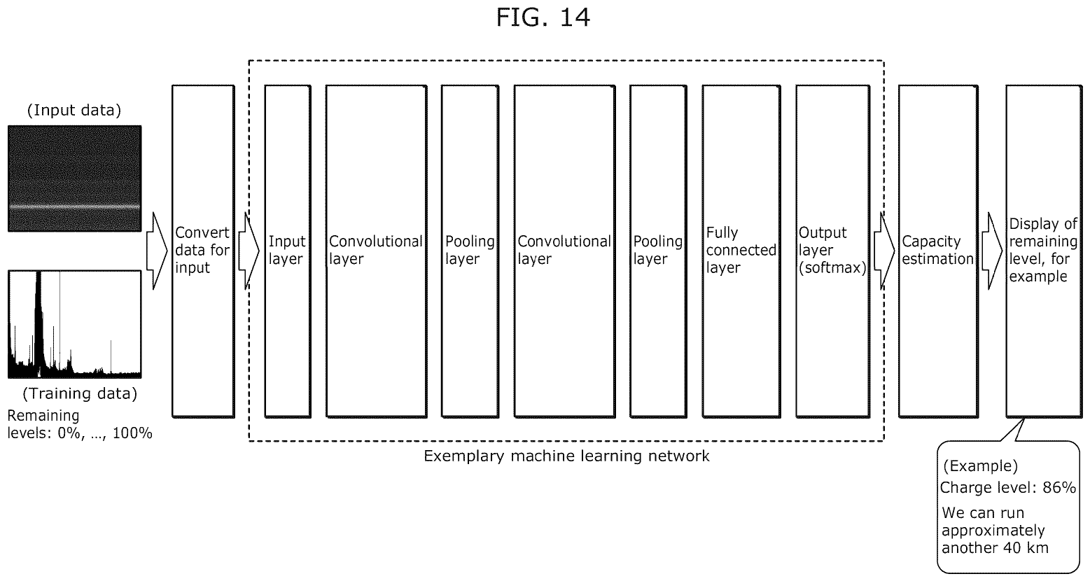

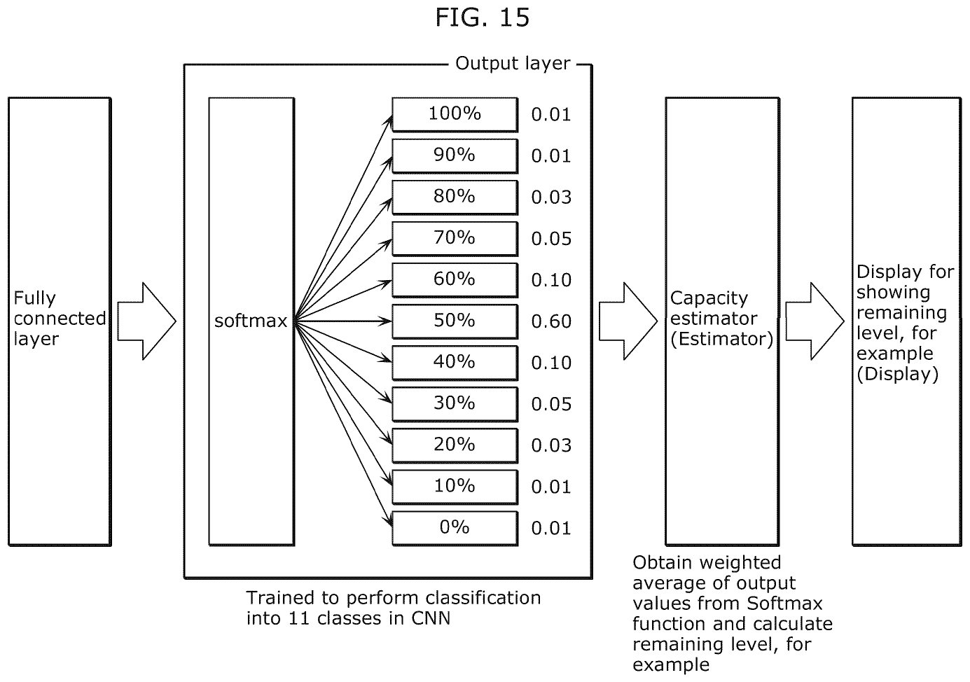

FIG. 14 is a diagram to describe an example of a structure of a machine learning model. FIG. 15 is a diagram to describe an output layer of the machine learning model. Note that training data shown in FIG. 14 will be described later in a training phase of the machine learning model. In the example of FIG. 14, the machine learning model is a convolutional neural network (CNN) having convolutional layers and pooling layers. Estimator 13c inputs sound information, such as a spectrogram image or a frequency characteristic image, into the trained machine learning model (i.e., the trained model) as input data. For example, as shown in FIG. 15, for the inputted sound information, a likelihood for each of 11 classes is calculated in the output layer of the trained model. In the output layer, the inputted sound information is classified by dividing charge levels (i.e., remaining battery levels) of the secondary battery from 0% to 100% into classes in increments of 10% and calculating a likelihood for each of these classes. The machine learning model includes a parameter adjusted, through training, to perform classification into the 11 classes according to the state of charge of the secondary battery. This parameter may be adjusted, for example, to perform classification by the state of charge for each state of degradation of the secondary battery.

With reference to FIG. 13 again, in step S231, estimator 13c obtains the sound information generated in step S22 as input data for the trained model, inputs the obtained sound information into the trained model, and obtains the result outputted from the trained model, i.e., the likelihood for each of the classes, which has been derived in the output layer.

Next, estimator 13c of state quantity estimation device 10 estimates the state quantity of secondary battery 1 based on the output results obtained in step S231 (S232). For example, estimator 13c estimates the state quantity of secondary battery 1 by obtaining a weighted average of output values from a Softmax function and then calculating an estimated value of the state quantity of secondary battery 1 as shown in FIG. 11.

### Operation Example 3

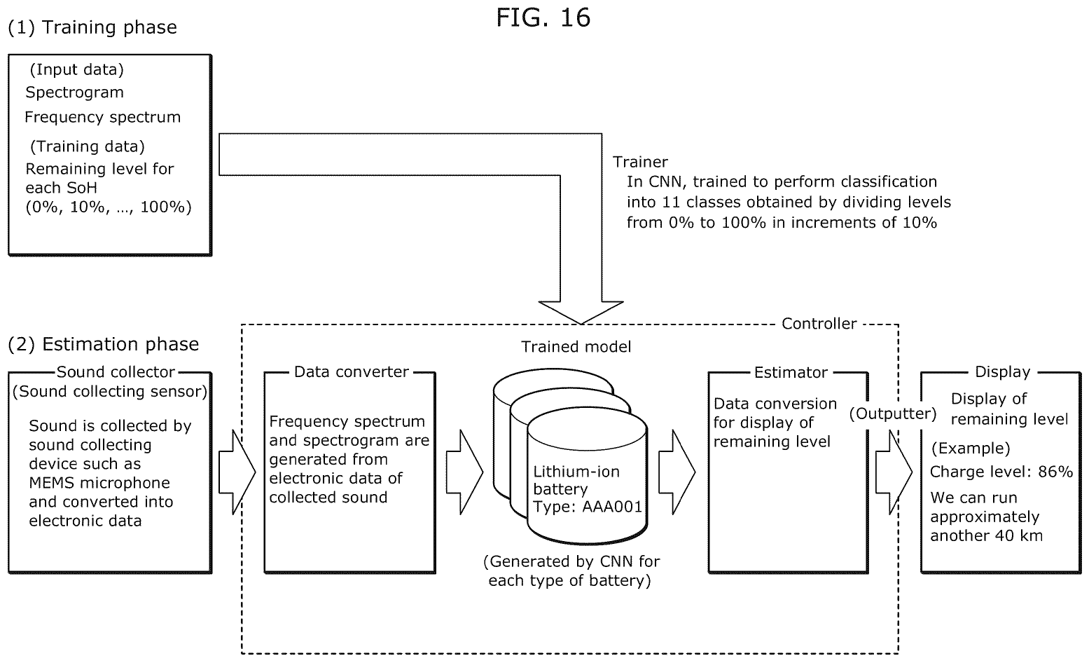

Next, Operation Example 3 describes an operation from training of a machine learning model to estimation of a state quantity of secondary battery 1 using the trained model. Operation Example 3 differs from Operation Example 2 in that a trained model is generated for each type of secondary battery 1, and estimator 13c obtains information indicating the type of secondary battery 1 to change the trained model to be used. FIG. 16 is a diagram showing an example of a training phase of the machine learning model and an estimation phase using the trained machine learning model.

State quantity estimation device 10 performs (1) Training phase, and then performs (2) Estimation phase (more specifically, a use phase of the trained model). First, in (1) Training phase, trainer 14 of state quantity estimation device 10 trains the machine learning model using training data. The training data is a data set including sound information and an annotation indicating at least one of a remaining battery level or a degree of degradation of secondary battery 1 from which the sound has been collected. In the example of FIG. 16, the training data is a data set including sound information and an annotation indicating a remaining battery level for each degree of degradation (i.e., SoH). The training data may also be prepared for each type of secondary battery 1. This allows state quantity estimation device 10 to change the trained model to be used according to the type of secondary battery 1. Thus, state quantity estimation device 10 can estimate the state quantity of secondary battery 1 more accurately. Trainer 14 trains the machine learning model to perform classification into 11 classes, which are obtained by dividing remaining battery levels from 0% to 100% in increments of 10%. When the training of the machine learning model is completed, trainer 14 updates the trained models stored in storage 15.

Subsequently, in (2) Estimation phase, sound collector 12 of state quantity estimation device 10 collects, in the vicinity of secondary battery 1 without contact with secondary battery 1, a sound emitted from secondary battery 1 during charge or discharge of secondary battery 1. Sound collector 12 then converts an electrical signal of the collected sound into a digital signal (also referred to as electronic data) and outputs the digital signal to controller 13.

Obtainer 13a of controller 13 obtains the sound electronic data outputted from sound collector 12 and outputs the obtained sound electronic data to data converter 13b.

Data converter 13b converts the obtained sound electronic data into a predetermined form of information. For example, the sound information may be a frequency spectrum or a spectrogram. The sound information may be an image or time-series numerical data. Data converter 13b outputs the sound information to estimator 13c.

Estimator 13c inputs the sound information obtained from data converter 13b into the trained model stored in storage 15. For example, when estimator 13c obtains information indicating a type of secondary battery 1, estimator 13c selects a trained model corresponding to that type from among the trained models stored in storage 15, and inputs the sound information into the selected trained model. Estimator 13c obtains a weighted average of output results outputted from the trained model (see FIG. 15) and calculates an estimated value of the state quantity. Furthermore, estimator 13c may convert data of the estimated value for display of the remaining battery level.

Outputter 13d outputs, to display 17, the data of the estimated value converted by estimator 13c.

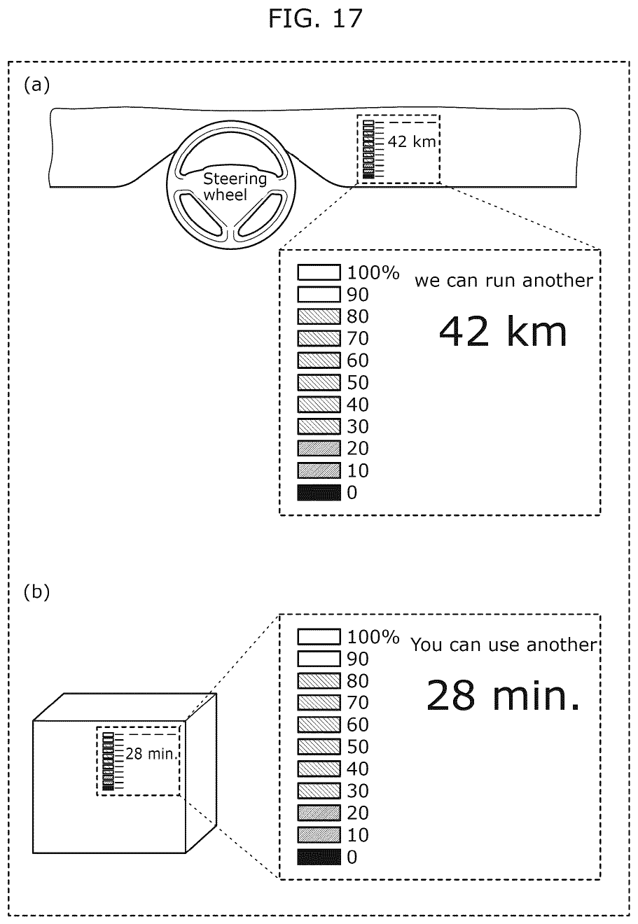

Display 17 displays the remaining battery level and other information based on the obtained data. Specifically, display 17 may display, based on the obtained data, the remaining level (also referred to as the charge level) of secondary battery 1 and information such as an operable time of a device using that secondary battery 1 as a power source. For example, if secondary battery 1 is used in an electric vehicle such as an electric car, an electric motorcycle, or an electric bicycle, display 17 may display the charge level of the secondary battery and a distance the electric vehicle can run as shown in FIG. 16. Display examples will be described with reference to FIG. 17. FIG. 17 is a diagram showing such display examples. In FIG. 17, (a) shows a display example on a display panel on a dashboard of an electric car equipped with secondary battery 1. The display panel shows a remaining battery level of secondary battery 1 and a distance the electric car can run. In (b) of FIG. 17, there is shown a display example on a display panel of a power supply unit equipped with secondary battery 1. The display panel shows a remaining battery level of secondary battery 1 and an operable time. As described above, display 17 may show display information including the state quantity of secondary battery 1.

[3. Effects, etc.]

As described above, state quantity estimation device 10 according to Embodiment 1 includes: sound collector 12 that collects, in the vicinity of secondary battery 1 without contact with secondary battery 1, a sound emitted from secondary battery 1 during charge or discharge of secondary battery 1; estimator 13c that estimates a state quantity indicating a state of secondary battery 1, based on information on the sound collected by sound collector 12; and outputter 13d that outputs the state quantity estimated by estimator 13c.

This eliminates a need for state quantity estimation device 10 to fully charge or fully discharge secondary battery 1 in order to measure the state quantity of secondary battery 1. Thus, state quantity estimation device 10 can quickly estimate the state quantity of secondary battery 1. Moreover, since state quantity estimation device 10 can estimate the state quantity based on the information on the sound collected in the vicinity of secondary battery 1 without contact with secondary battery 1, state quantity estimation device can estimate the state quantity without contact with secondary battery 1. This allows state quantity estimation device 10 to estimate the state quantity of secondary battery 1, for example, placed inside an enclosure without removing secondary battery 1 from the enclosure. Thus, state quantity estimation device 10 can quickly estimate the state quantity of secondary battery 1 in a non-contact manner.

In state quantity estimation device 10 according to Embodiment 1, estimator 13c may estimate the state quantity based on an output result obtained by inputting the information on the sound into a trained model that is a machine learning model having undergone training.

This allows state quantity estimation device 10 to more easily extract regularity (i.e., a feature quantity) of the information on the sound by using the trained machine learning model. Thus, state quantity estimation device 10 can estimate the state quantity of secondary battery 1 more conveniently.

In state quantity estimation device 10 according to Embodiment 1, the machine learning model may be trained using training data, and the training data may be a data set including the information on the sound and an annotation indicating at least one of a remaining battery level or a degree of degradation of the secondary battery from which the sound has been collected.

This improves the training accuracy of the machine learning model, and state quantity estimation device 10 can therefore estimate the state of secondary battery 1 with high accuracy.

In state quantity estimation device 10 according to Embodiment 1, the information on the sound may be information including: a frequency band of the sound; and at least one of a duration of the sound, a sound pressure of the sound, or a waveform of the sound. Moreover, the information on the sound may be in a form of time-series numerical data of the sound, a spectrogram image of the sound, or a frequency characteristic image of the sound, for example.

This allows state quantity estimation device 10 to more easily estimate the state quantity of secondary battery 1 based on the regularity (i.e., the feature quantity) of the information on the sound.

In state quantity estimation device 10 according to Embodiment 1, the state quantity may be a value of an indicator indicating at least one of a state of charge of the secondary battery or a state of degradation of the secondary battery.

This allows state quantity estimation device 10 to estimate the state of secondary battery 1 more accurately.

In state quantity estimation device 10 according to Embodiment 1, the state quantity may be a value of at least one of a state of charge (SoC) or a state of health (SoH).

This allows state quantity estimation device 10 to estimate the state quantity of secondary battery 1 based on the value of the at least one of the SoC or the SoH.

In state quantity estimation device 10 according to Embodiment 1, the sound may be a sound with a frequency in an ultrasonic band.

This makes state quantity estimation device 10 less affected by noise as compared to a case of a sound in a frequency band that can be perceived by the human sense of hearing (i.e., an audible sound). Thus, the state quantity of secondary battery 1 can be estimated more accurately.

### Embodiment 2

Next, Embodiment 2 will be specifically described with reference to the drawings.

[State Quantity Estimation System]

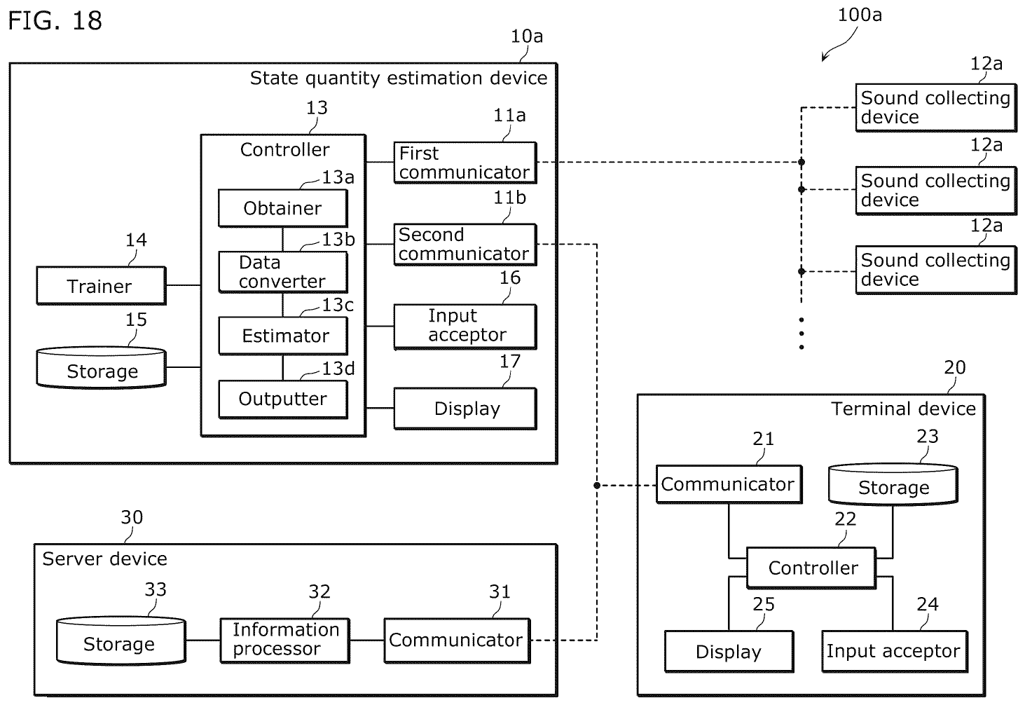

FIG. 18 is a diagram illustrating an example of state quantity estimation system 100a to which state quantity estimation device 10a is applied, according to Embodiment 2.

While the example in which state quantity estimation device includes sound collector 12 has been described in Embodiment 1, Embodiment 2 differs from Embodiment 1 in that state quantity estimation device 10a includes no sound collector 12 and obtains information on a sound collected by sound collecting device 12a connected via communication. The following description will mainly focus on points different from those in Embodiment 1, and duplicated descriptions will be simplified or omitted.

[1. Configuration]

First, a configuration of state quantity estimation system 100a will be described with reference to FIG. 18. State quantity estimation system 100a includes, for example, state quantity estimation device 10a, one or more sound collecting devices 12a, and terminal device 20. As shown in FIG. 18, state quantity estimation system 100a may further include server device 30. Configurations of these components will be described below. Note that terminal device 20 is the same as that described in Embodiment 1 and will not be therefore described individually.

[State Quantity Estimation Device]

State quantity estimation device 10a obtains a sound emitted from secondary battery 1 during charge or discharge of secondary battery 1 and collected by sound collecting device 12a in the vicinity of secondary battery 1 without contact with secondary battery 1. State quantity estimation device 10a then estimates a state quantity indicating a state of the secondary battery, based on information on the obtained sound and outputs the estimated state quantity. If state quantity estimation device 10a obtains sounds collected by the plurality of sound collecting devices 12a, state quantity estimation device 10a may further obtain identification information and location information of each sound collecting device 12a.

State quantity estimation device 10a differs from state quantity estimation device 10 according to Embodiment 1 in that state quantity estimation device 10a includes no sound collector 12 and includes first communicator 11a and second communicator 11b.

First communicator 11a is a communication module (a communication circuit) for communicating with sound collecting device 12a. First communicator 11a may be, for example, a wireless communication circuit that performs wireless communication or a wired communication circuit that performs wired communication. The standard of such communication performed by first communicator 11a is not limited to any particular communications standard. First communicator 11a is, for example, a local communication circuit.

Second communicator 11b is a communication module (a communication circuit) for communicating with terminal device 20 and server device 30. Second communicator 11b may be, for example, a wireless communication circuit that performs wireless communication or a wired communication circuit that performs wired communication. The standard of such communication performed by second communicator 11b is not limited to any particular communications standard. Second communicator 11b is, for example, a wide-area communication circuit.

[Sound Collecting Device]

Sound collecting device 12a is disposed in the vicinity of secondary battery 1 without contact with secondary battery 1. Sound collecting device 12a converts the collected sound into an electrical signal (e.g., a digital signal), and outputs the electrical signal to state quantity estimation device 10a. Sound collecting device 12a includes a communicator (not shown) for communicating with state quantity estimation device 10a. Sound collecting device 12a may be configured integrally with a sound collector (e.g., a microphone) or separately from such a sound collector. In the latter case, sound collecting device 12a may obtain a sound collected by the sound collector via communication.

If state quantity estimation system 100a includes the plurality of sound collecting devices 12a, each sound collecting device 12a may output its own identification information and location information along with the digital signal of the collected sound.

[Server Device]

Server device 30 is, for example, a client server. Server device 30 includes, for example, communicator 31, information processor 32, and storage 33. Server device 30 is communicatively connected to one or more state quantity estimation devices 10a, for example, and may, for example, provide training data to state quantity estimation devices 10a or provide display information according to estimation results of state quantity estimation devices 10a.

Communicator 31 is a communication circuit (a communication module) used by server device 30 to communicate with state quantity estimation device 10a via a wide-area communication network. The communication performed by communicator 31 is, for example, wired communication, but may also be wireless communication. The communications standard used for such communication is also not limited to any particular communications standard.

Information processor 32 processes information related to operations of server device 30. Information processor 32 is implemented by a microcomputer, for example, but may also be implemented by a processor.

Storage 33 is a storage device in which control programs to be executed by information processor 32, for example, are stored. Storage 33 is implemented by a hard disk drive (HDD), for example, but may also be implemented by a semiconductor memory, for example.

[2. Operations]

Operations of state quantity estimation device 10a according to Embodiment 2 will be described next in terms of differences from Embodiment 1.

Obtainer 13a of state quantity estimation device 10a obtains the sound collected by sound collecting device 12a via first communicator 11a, and outputs the obtained sound to data converter 13b.

Estimator 13c estimates the state quantity of the secondary battery based on sound information generated by data converter 13b. At this time, estimator 13c may estimate the state quantity based on output results obtained by inputting the sound information into a trained model that has been trained using the training data provided by server device 30. Estimator 13c may also output the display information provided by server device 30 according to the estimation result. The display information provided by server device 30 may be, for example, about the number of times the secondary battery can be recharged hereafter, when to replace the secondary battery, problems that may occur due to the state of degradation, or how to avoid such problems.

[3. Effects, etc.]

As described above, state quantity estimation device 10a according to Embodiment 2 can perform the more-detailed estimation of the state quantity of secondary battery 1 by distributing the processing to other devices or by performing the processing in cooperation with other devices.

### OTHER EMBODIMENTS

The state quantity estimation devices and the state quantity estimation methods according to one or more aspects of the present disclosure have been described above based on the embodiments described above. However, the present disclosure is not limited to these embodiments. Variations that are obtained by making, to the above embodiments, various changes that may be conceived of by those skilled in the art and embodiments that are obtained by combining any components of the different embodiments may also be included in the scope of the one or more aspects of the present disclosure without departing from the spirit of the present disclosure.

For example, the state quantity estimation devices according to the above embodiments may each obtain environmental data, such as a temperature around the secondary battery at the time of collecting the sound emitted from the secondary battery, and estimate the state quantity of the secondary battery based on the sound information, the environmental data, and identification information such as the type of the secondary battery. The environmental data is, for example, about the temperature of the environment in which the secondary battery is placed, a voltage applied to the secondary battery, or a type of current (e.g., a pulsed current) to be passed through the secondary battery. This improves the possibility of being able to estimate the state of the secondary battery more accurately.

For example, some or all of the components of each of the state quantity estimation devices according to the above embodiments may be configured as a single system LSI (Large Scale Integrated) chip. For example, the state quantity estimation device may be configured as a system LSI chip including a sound collector, an estimator, and an outputter. Note that the system LSI chip may include no sound collector. In such a case, the system LSI chip may include an obtainer that obtains information on a sound collected by a sound collector.

The system LSI chip is a super multi-functional LSI chip manufactured by integrating a plurality of constituent elements on a single chip. Specifically, the system LSI chip is a computer system configured to include, for example, a microprocessor, a read only memory (ROM), and a random access memory (RAM). The ROM stores computer programs. The system LSI chip achieves its functions as a result of the microprocessor operating according to the computer programs.

Although referred to here as a system LSI chip, such a component may also be referred to as an IC, an LSI chip, a super LSI chip, or an ultra LSI chip, depending on the degree of integration. The circuit integration technique is not limited to LSI, and circuit integration may be realized using a dedicated circuit or a general-purpose processor. A field programmable gate array (FPGA), which can be programmed after the manufacturing of the LSI chip, or a reconfigurable processor, which can reconfigure the connections and settings of circuit cells inside the LSI chip, may also be used.

Furthermore, as a matter of course, if a circuit integration technology that replaces LSI appears through advances in semiconductor technology or due to another derivative technology, the integration of functional blocks may be performed using that technology. Application of biotechnologies, for example, may be conceivable.

An aspect of the present disclosure may be not only such a state quantity estimation device, but also a state quantity estimation method in which the characteristic constituent elements included in the device are converted to steps. An aspect of the present disclosure may also be a computer program that causes a computer to execute each of the characteristic steps included in the state quantity estimation method. An aspect of the present disclosure may also be a non-transitory computer-readable recording medium on which such a computer program is recorded.

### INDUSTRIAL APPLICABILITY

According to the present disclosure, a sound emitted from a secondary battery can be collected at a position not in contact with, but in proximity to, the secondary battery. Thus, without removing a secondary battery held inside an enclosure from the enclosure, for example, the state quantity of the secondary battery can be estimated. As described above, since a state quantity of a secondary battery can be estimated more conveniently according to the present disclosure, the present disclosure can be applied to various fields.

1. A state quantity estimation device comprising:
a sound collector that collects, in a vicinity of a secondary battery without contact with the secondary battery, a sound emitted from the secondary battery during charge or discharge of the secondary battery;
an estimator that estimates a state quantity indicating a state of the secondary battery, based on information on the sound collected by the sound collector; and
an outputter that outputs the state quantity estimated by the estimator.

2. The state quantity estimation device according to claim 1,
wherein the estimator estimates the state quantity based on an output result obtained by inputting the information on the sound into a trained model that is a machine learning model having undergone training.

3. The state quantity estimation device according to claim 2,
wherein the machine learning model is trained using training data, and
the training data is a data set including the information on the sound and an annotation indicating at least one of a remaining battery level or a degree of degradation of the secondary battery from which the sound has been collected.

4. The state quantity estimation device according to claim 1,
wherein the information on the sound is information including:
a frequency band of the sound; and at least one of a duration of the sound, a sound pressure of the sound, or a waveform of the sound.

5. The state quantity estimation device according to claim 1,
wherein the information on the sound is in a form of time-series numerical data of the sound, a spectrogram image of the sound, or a frequency characteristic image of the sound.

6. The state quantity estimation device according to claim 1,
wherein the state quantity is a value of an indicator indicating at least one of a state of charge of the secondary battery or a state of degradation of the secondary battery.

7. The state quantity estimation device according to claim 1,
wherein the state quantity is a value of at least one of a state of charge (SoC) or a state of health (SoH).

8. The state quantity estimation device according to claim 1,
wherein the sound is a sound with a frequency in an ultrasonic band.

9. A state quantity estimation method comprising:
collecting, in a vicinity of a secondary battery without contact with the secondary battery, a sound emitted from the secondary battery during charge or discharge of the secondary battery;
estimating a state quantity indicating a state of the secondary battery, based on information on the sound collected in the collecting; and
outputting the state quantity estimated in the estimating.

10. A non-transitory computer-readable recording medium having recorded thereon a program for causing a computer to execute the state quantity estimation method according to claim 9.
